(19) United States
(12) Patent Application Publication
(10) Pub. No.: US 2019/0118671 A1
(43) Pub. Date: Apr. 25, 2019

(54) DEVICE, METHOD AND SYSTEM FOR MONITORING A CHARGING CABLE ON A CHARGING STATION

(71) Applicants: Stefan Helnerus, Arnsberg (DE); Jürgen Waffner, Essen (DE)

(72) Inventors: Stefan Helnerus, Arnsberg (DE); Jürgen Waffner, Essen (DE)

(73) Assignee: innogy SE, Essen (DE)

(21) Appl. No.: 16/222,478

(22) Filed: Dec. 17, 2018

Related U.S. Application Data
(63) Continuation of application No. PCT/EP2017/059695, filed on Apr. 25, 2017.

(30) Foreign Application Priority Data
Jun. 17, 2016 (DE) 10 2016 111 094.9

(51) Int. Cl. B60L 53/10; B60L 53/14; H02J 7/00; G01R 31/12; B60L 53/16

(52) U.S. Cl. CPC B60L 53/10; B60L 53/14; B60L 53/16; G01R 31/1272; H02J 7/0042

(57) ABSTRACT

Disclosed are embodiments of a charging station. The charging station includes a charging cable attached to the charging station in a fixed manner. At least one charging cable holder and at least one monitoring apparatus are arranged on the charging station. The monitoring apparatus is configured to monitor whether the charging cable is arranged correctly on the charging station, and the monitoring apparatus monitors whether the charging cable is placed around the charging cable holder in at least one loop.

### CROSS-REFERENCE TO RELATED PATENT APPLICATIONS

This patent application is a continuation of PCT/EP2017/059695, filed Apr. 25, 2017, which claims priority to German Application No. 10 2016 111 094.9, filed Jun. 17, 2016, the entire teachings and disclosure of which are incorporated herein by reference thereto.

### FIELD

The subject matter relates to an apparatus, a method and a system for monitoring a charging cable at a charging station.

### BACKGROUND

Charging stations for electric vehicles are conceivable in two variants. In a first variant, the charging station comprises only a mounting means, in particular a socket for a plug of a charging cable. The charging cable is carried by the user of the electric vehicle. For the charging operation, the plug of the charging cable is plugged into the charging station or the socket of the charging station. Following the end of the charging operation, the user removes the charging cable from the charging station and takes it back with them. In this case, there is no danger of the charging cable laying on the pavement outside of a charging operation and thus forming a stumbling obstacle.

In a second variant, the charging cable is attached to the charging station in a fixed manner, i.e. the charging cable is permanently connected to the charging station. A plug or a socket is provided at the end of the charging cable which can be plugged into a receiving portion on a vehicle. For a charging operation, the user of an electric vehicle takes the charging cable and connects it to their vehicle. However, following the end of the charging operation, it cannot as yet be ensured that the charging cable remaining at the charging station is placed back in an orderly manner and is not left on the pavement in a disorderly manner and therefore forms a stumbling obstacle there.

Automatic roll-up apparatuses, which pull the charging cable back into the charging station, are complex and prone to failure. This is in particular disadvantageous in the case of large-scale use of charging stations as the maintenance cost is disproportionally high.

A charging cable attached in a fixed manner must therefore as far as possible be prevented from laying in a disorderly manner at the charging station following the charging operation and from forming a stumbling obstacle. It should be ensured that the charging cable is wound up around a cable holder following the charging operation. This also ensures that the charging cable suffers less damage, in particular in the case of the charging cable being driven over by a vehicle or the like.

For this reason, the object underlying the subject matter is to provide an apparatus and a method and a system in the case of which charging station charging cables attached in a fixed manner do not form a stumbling obstacle.

### BRIEF SUMMARY

This object is achieved by a charging station, a method, and a system as shown and described in the present application.

The inventors have recognised that it is possible to monitor the position of the charging cable at the charging station by means of monitoring apparatuses. To this end, a charging station, to which a charging cable is attached in a fixed manner, is fitted with a charging cable holder and a monitoring apparatus. The charging cable holder is a mechanical mounting means for a charging cable. The charging cable holder is in particular an arched or semi-circular mounting for a charging cable. The charging cable holder is formed to mount charging cables in a plurality of loops or windings.

In order to ensure that the charging cable is actually wound around the charging cable holder, it is proposed that a monitoring apparatus be provided configured to monitor the position of the charging cable at the charging station. The monitoring apparatus monitors whether the charging cable is placed around the charging cable holder in at least one loop.

A charging operation can generally be assigned to a user. If the charging operation has ended, the user is instructed to wind the charging cable around the charging cable holder in at least one loop, preferably a plurality of loops. The number of loops is in particular dependent on the length of the charging cable and it must be ensured that the charging cable is not left laying freely on the ground at its loose end. If it is now monitored by means of the monitoring apparatus whether or not the charging cable was placed around the charging cable holder in a corresponding number of loops, it can be determined whether the user of the charging station has actually also put the charging cable back in an orderly manner.

If this is not the case, the user can possibly be informed of this. In the case of multiple violations, the user may for example be excluded from the charging system or be given a penalty. However, it is also possible for a reward system to be introduced, in particular it may be possible for the calculated energy price to depend on whether or not the user has placed the charging cable around the charging cable holder at the end of the charging operation. Depending on a signal from the monitoring apparatus, a price signal may be varied which determines the price for the related amount of energy. A price deduction may for example be given if the monitoring apparatus has reported that a charging cable has been put back in an orderly manner.

Other bonus systems are also conceivable. For example, a number of successful operations can be counted in which the charging cable was put back and a bonus can be paid in the case of a certain number.

It is now possible to determine by means of the present charging station whether or not the charging cable was placed correctly on the charging cable holder at the end of a charging operation. This means that security at the charging stations is increased whereby the users can be persuaded by suitable bonus or penalty systems to put the charging cable back correctly. The number of operations in which the charging cable lays on the ground around the charging station in a disorderly manner can be reduced.

Monitoring whether the charging cable is placed around the charging cable holder in at least one loop can be carried out in a number of ways. Monitoring can in particular be carried out via radio, weighing, magnetically, optically, electrically, electronically or the like. Different variants of monitoring apparatuses can be used individually or in combination with one another in order to be able to determine the position of the charging cable at the charging cable holder.

According to one embodiment, it is proposed that the monitoring apparatus comprises a wireless reading apparatus configured for near-field communication. Near-field communication can in particular be carried out according to the NFC standard or the Bluetooth standard or another suitable standard which operates by means of magnetic or electromagnetic fields. At least one near-field detection of an identification means arranged on the charging cable can be carried out by means of the reading apparatus. An identification means can be a passive identification means which is activated by a reading field of the reading apparatus and in particular either changes the reading field or the reading field strength according to its identifier or emits its own identifier in a transmission field, in particular at a transmission frequency that is different to the reading field.

The identification means can in particular be arranged in or on the insulation on the charging cable. By means of the identification means and the reading apparatus, it is possible to monitor whether the charging cable is wound around the charging cable holder in at least one loop. By virtue of the reading apparatus capturing a determined spatial region (and being capable of being limited to this region) and verifying whether the identification means can be read in this region, it can be determined whether the charging cable with its identification means is actually in this region and therefore is arranged in a determined position at the charging station. The region can be defined such that only when the charging cable is wound around the charging cable holder are the identification means arranged in the corresponding region. Therefore, it can be ensured that the reading apparatus reads the identification means when the charging cable is correctly wound on the charging cable holder.

According to one embodiment, the monitoring apparatus can also comprise a weighing apparatus. The weight of the charging cable holder together with the charging cable possibly arranged thereon can be measured by means of the weighing apparatus. Only when the charging cable is wound around the charging cable holder is a weighing force exerted on the charging cable holder and consequently the weighing apparatus. If the charging cable is not wound around the charging cable holder sufficiently, its free end may still lay on the ground. This end laying on the ground no longer exerts a weighing force on the charging cable holder. It can therefore be determined by means of the weighing apparatus whether the charging cable is wound fully around the charging cable holder, in particular whether the free end of the charging cable no longer lays on the ground. This is possible by a comparison of the measurement result of the weighing apparatus with a threshold value. The treshold value can e.g. be taught when the charging station is installed. Only when the weighed weight of the charging station is above this limit value can a wound-up cable be deduced.

According to one embodiment, it is proposed that the monitoring apparatus comprises an optical reading apparatus. An optical reading apparatus can be configured as a light barrier and/or image capturing means, for example a camera or video device. It is possible to optically detect the charging cable arranged on the charging cable holder by means of the optical reading apparatus. In the case of optical detection, it is, on the one hand, possible to capture an image of the charging cable holder together with the charging cable. It is in particular possible for an optics to be configured to record the charging cable holder from above. It can then be measured how many times the charging cable is wound on the charging cable holder. This is possible, for example, by virtue of using pattern detection to detect whether the charging cable holder or a charging cable were detected in the image. If a charging cable is detected, the individual windings of the charging cable can be distinguished from one another e.g. by colour gradients or contrast gradients and it can therefore be determined how often the charging cable is placed around the charging cable holder.

Optical identification means can also be arranged on the charging cable, for example in the form of barcodes, QR codes, colour coding or the like and can be detected by the reading apparatus. If the optical identification means are detected in a previously-defined position on the charging cable holder by the reading apparatus, it can be deduced from this that the charging cable is wound correctly around the charging cable holder. It is possible in particular to teach the reading apparatus when the charging station is installed and possibly teach images which show a correctly wound-up charging cable. The image actually captured can be compared with the taught images and a value of the deviation can be determined. If the value of the deviation is below a limit value, this can be assessed as an indication that the charging cable is correctly wound around the charging cable holder. It is therefore possible to monitor by means of the optical reading apparatus whether the charging cable is wound around the charging cable holder in at least one loop.

According to one embodiment, it is proposed that the monitoring apparatus comprises a proximity sensor. A proximity sensor can for example be configured to detect a movement of the charging cable arranged on the charging cable holder. Therefore, when the proximity sensor is arranged directly on the charging cable holder, it can for example be determined if the charging cable is placed on the charging cable holder. The charging cable must be passed by the proximity sensor when it is placed on the charging cable holder. The direction of the movement can be detected by a suitable arrangement of one or two proximity sensors. If a movement of the charging cable towards the charging cable holder has been detected, it can be deduced therefrom that the charging cable was placed in a winding around the charging cable holder. The number of windings or coils which the charging cable must be placed around the charging cable holder can be defined. The proximity sensor can determine how often the charging cable passes by the proximity sensor and was moved in the direction of the charging cable holder. It can be concluded therefrom whether the charging cable was wound around the charging cable holder in at least one loop.

As already explained, the monitoring apparatus can be configured to capture optical or electronic identification means on the charging cable. For this reason, according to one embodiment it is proposed that at least two optical or electronic identification means are arranged on the charging cable at distances to one another. The identification means can in particular be barcodes, near-field tags, NFC beacons, colour codings, QR codes or the like. A distance between respectively two identification means may thus be that this distance corresponds to the length of the charging cable required to place said charging cable around the charging cable holder exactly once in a loop. This leads to the identification means respectively laying in roughly the same position in the region of the charging station when wound correctly. The identification means can therefore be captured in a very specific, defined spatial region by means of the monitoring apparatus.

According to one embodiment, the identifications means can be captured by the monitoring apparatus. A suitable spacing of the identification means to one another ensures that the identification means lay roughly in the same region when the charging cable is placed around the charging cable holder. As a result, it is possible for the monitoring apparatus to be configured to capture the identification means in a spatially limited region. By limiting the region in which the monitoring apparatus can detect the identification means, it can be ensured that only a correctly wound-up charging cable is detected as such.

The charging cable is generally wound not only in one loop, but rather in two or a plurality of loops around the charging cable holder. In order to detect whether the charging cable was wound around the charging cable holder in the correct number and in the correct manner, the monitoring apparatus can be configured to check a number or an identifier of identification means that is representative of the winding of the charging cable around the charging cable holder. To this end, a corresponding number or corresponding identifiers of identification means are initially stored in the monitoring apparatus that are representative of the winding of the charging cable around the charging cable holder. While verifying whether the charging cable was wound around the charging cable holder, the monitoring apparatus can check whether the detected number or the detected identifiers correspond to those which are stored. In this case, it must be considered that the number and/or the identifiers can be taught when the charging station is installed. In this case, the charging cable can be placed around the charging cable holder in one or a plurality of configurations which are considered correct and the number and/or identifiers are read in these positions and are stored as comparative values. In the case of a positive comparison of the current measurement values with the stored measurement values, the monitoring apparatus can conclude therefrom that the charging cable was wound correctly around the charging cable holder. If the number was not correct and not all identifiers were detected, this may be an indication that the charging cable was not correctly wound around the charging cable holder and the monitoring apparatus can emit a corresponding signal.

According to one embodiment, it is proposed that the identification means are coded such that a charging cable is uniquely identifiable by means of the identification means. The identification can for example be carried out by a binary coding with a check digit such that each identification means can be uniquely identified. A unique identification of the identification means allows the identification means to be distinguished from one another. It is also possible for two or more charging cables to be attached to the charging station for example. In order to ensure that the charging cable was wound around the correct charging cable holder, the charging cable can also be coded in the identification means. It can therefore be verified by the monitoring apparatus whether, on the one hand, a charging cable was wound correctly around the charging cable holder at all and, on the other hand, whether this charging cable is also the correct charging cable and not perhaps the second charging cable of the charging station which should be wound around another charging cable holder. The coding can for example be carried out by a binary coding with a check digit such that each charging cable at a charging station can be uniquely identified.

According to one embodiment, it is proposed that a charging electronics is arranged in the charging station, that the charging electronics is configured to detect an end of a charging operation and that the charging electronics activates the monitoring apparatus, in particular for at least one defined period when an end of a charging operation is detected.

It has been recognised that the monitoring apparatus does not have to be permanently active. Detecting whether a charging cable was wound correctly on a charging cable holder is in particular important when a charging operation has ended. At this time, the user removes the charging cable from their vehicle. Accordingly, the user should then wind the charging cable on the charging cable holder. Monitoring is therefore necessary from the end of the charging operation, in particular for a determined period. It can be assumed that the user will wind the charging cable around the charging cable holder within the few next minutes. The charging electronics can therefore firstly detect the end of the charging operation in order to subsequently activate the monitoring apparatus for a defined period, for example one minute, five minutes or fifteen minutes. In this period, the monitoring apparatus monitors whether the charging cable was wound correctly around the charging cable holder.

According to one embodiment, it is proposed that the monitoring apparatus, after being activated by the charging electronics, monitors for a defined period whether the charging cable is wound around the charging cable holder in at least one loop. It has been recognised that the charging cable is wound on the charging cable holder by the user only within a certain period. If this period has elapsed, it must be assumed with the highest probability that the charging cable will no longer be placed on the charging cable holder by the user. This period is preferably one, in particular two to five minutes following the end of the charging operation. In this defined period, the monitoring apparatus is active and checks whether the charging cable was placed on the charging cable holder.

Following the end of the charging operation, it is not only important to know whether the charging cable was placed correctly on the charging cable holder, but also whether the charging cable is electrically free of faults. The insulation resistance between the individual conductors of the cable is in particular relevant for the electrical safety of the charging cable. It is therefore also proposed that the monitoring apparatus, after being activated by the charging electronics, monitors the electrical state of the charging cable. In this case, an insulation resistance can in particular be measured between at least respectively two conductors of the charging cable. A threshold value can indicate how high the insulation resistance normally has to be. This threshold value should not be undercut. The monitoring apparatus therefore compares the measured value with the threshold value.

In order to derive an action from the measurement of the monitoring apparatus, it is necessary for the monitoring apparatus to emit the result of the verification. Therefore, it is proposed that the monitoring apparatus emits a confirmation signal when it has been detected within the defined period that the charging cable is wound around the charging cable holder and/or the electrical state of the charging cable has been positively monitored. Positive monitoring can be understood as the measured values of the insulation resistance being above the threshold value. The insulation is therefore provided. This is a positive result and can be assessed as positive monitoring.

It is also possible that the monitoring apparatus emits an error signal at the end of the period without it being detected that the charging cable was wound around the charging cable holder and/or the electrical state of the charging cable was negatively monitored. The monitoring apparatus therefore emits either a confirmation signal or an error signal at the end of a defined period. Depending on this, the above-mentioned bonus and/or penalty system can for example be triggered.

According to one embodiment, it is proposed that a mounting socket is provided for a charging cable plug of the charging cable in the charging station. The mounting socket serves to mechanically receive the charging cable plug which is arranged at the free end of the attached cable. A testing apparatus is preferably arranged in the mounting socket. The testing apparatus is configured to test the presence of the charging cable plug in the mounting socket. To this end, the testing apparatus can in particular comprise a limit switch, a Hall sensor and/or a microswitch. The testing apparatus, using the corresponding sensors, can test whether the charging cable plug was plugged into the mounting socket.

According to one embodiment, it is proposed that the testing apparatus emits a confirmation signal when the presence of the charging cable plug is detected. The confirmation signal of the testing apparatus can be different to the confirmation signal of the monitoring apparatus. This may in particular be a first and a second confirmation signal. When both confirmation signals are present, it can be concluded therefrom that the charging cable together with charging cable plug was correctly arranged on the charging station.

For this reason, it is proposed that a processor of the charging station monitors a confirmation signal from the monitoring apparatus and/or a confirmation signal from the testing apparatus and emits a release signal when one or both confirmation signals are received within a defined time frame following the detected end of the charging operation. The release signal can be used to activate the above-described bonus and/or penalty system. It can be signalled by means of the release signal that the charging cable and possibly also the charging cable plug was correctly stowed on the charging station.

A further aspect is a method for monitoring a charging cable at a charging station, the charging cable being attached to the charging station in which it is monitored by means of a monitoring apparatus whether the charging cable is placed around the charging cable holder in at least one loop. To this end, monitoring apparatuses are in particular used, as described above. The method is suited for operating the above-described charging station corresponding to the above description.

It may happen that the type of winding differs from charging station to charging station. It may therefore be sensible to teach the charging cable or the winding of the charging cable around the charging cable holder at the charging station, as was to some extent already described above. To this end, it is also proposed that when the charging cable is installed the monitoring apparatus is taught on the charging station such that measurement values from the monitoring apparatus are recorded when the charging cable is placed around the charging cable holder in at least one loop. The measurement values of the monitoring apparatus may then be representative of the charging cable being placed correctly around the charging cable holder. In the case of teaching, the charging cable is placed around the charging cable holder, as desired. The monitoring apparatus then records the measurement values in order to consequently compare measured values with these taught values. In this case, it is possible in the case of teaching, to teach different positions or configurations of the charging cable at the charging cable holder. It is for example conceivable for many different windings around the charging cable holder to still be assessed as correct winding up. The number of loops can in particular be distinguished for the different configurations. It may also be relevant for the charging cable not to lay with its free end on the ground. Different windings can therefore be taught at the monitoring apparatus when the charging cable is installed. Each winding configuration can provide its own measurement values which can be respectively stored as a set of limit values.

During operation, the recorded measurement values can be used as limit values for determining whether the charging cable is placed around the cable holder in at least one loop. It is therefore also proposed that the recorded measurement values are stored as limit values for determining whether the charging cable is placed around the charging cable holder in at least one loop.

According to one embodiment, it is proposed that in order to detect whether the charging cable is placed around the cable holder in at least one loop, measurement values from the monitoring apparatus are compared with previously-determined threshold values. In this case, sets of threshold values for the most varied windings can be stored in the monitoring apparatus. As long as the measured values are within the threshold values of a determined group, it can be concluded therefrom that the charging cable was placed correctly around the charging cable holder.

It is possible by means of the optical identification means to capture an image of the charging station. Pattern detection can be carried out in the image of the charging station such that the charging cable holder and the charging cable are detected. The position of the charging cable in relation to the charging cable holder can then be determined in the image. This can in particular be relevant if the image was recorded by an external camera arranged outside of the charging station. For example, the user can record an image of the charging station together with the charging cable using their mobile end device, e.g. smartphone in order to utilise a bonus system. They can for example do this when they have wound the charging cable correctly around the charging cable holder. In this image, the charging cable and the charging cable holder are differentiated from the charging station in particular in contrast and/or colour. It is possible by means of pattern recognition to capture the charging cable and the charging cable holder by for example these differentiations in contrast and/or colour being assessed.

It is also possible to detect whether or not the charging cable lays with its free end on the ground. In the case of pattern recognition and subsequent assessment of the pattern, this can also be compared again with threshold values and it can thus be detected whether the position of the charging cable in relation to the charging cable holder is at a determined threshold value. If this is the case, a bonus and/or penalty system can for example be triggered in a server.

According to one embodiment, it is proposed that an optical identification means of the charging station, in particular a QR code is captured in the image of the charging station. Such a QR code or other coloured coding can be applied to the charging station and captured in the image. It is therefore possible to detect, by means of the optical identification means which charging station is captured in the image. The optical identification means is in this case for example an external camera, for example a camera in a smartphone or in another mobile end device. The user records not only the charging cable and the charging cable holder, but also the rest of the charging station in their image. In this case, the coding of the charging station, for example the QR code can be detected in the image and it can be determined which charging station the user has recorded. In a corresponding mobile application, this image can then be sent to a server for assessment.

For this reason, it is also proposed that a mobile communication device spatially separated from the charging station is used in a system with a charging station according to any one of the preceding claims. The optical reading apparatus is formed by means of this mobile communication device. The monitoring apparatus is therefore spatially separated from the charging station.

### BRIEF DESCRIPTION OF THE DRAWINGS

The subject matter is explained in more detail below with reference to a drawing showing exemplary embodiments. In the drawing:

FIG. 1 shows a charging station according to an exemplary embodiment;

FIG. 2 shows a charging station with a wound-up charging cable;

FIG. 3 shows a charging station with a wound-up charging cable;

FIG. 4 shows a charging station with two separated charging cables;

FIG. 5 shows a schematic view of a charging cable with identification means;

FIG. 6 shows a schematic view of an arrangement of a monitoring apparatus according to one exemplary embodiment;

FIG. 7 shows a schematic view of an arrangement of a monitoring apparatus according to one exemplary embodiment;

FIG. 8 shows a schematic view of an arrangement of a monitoring apparatus according to one exemplary embodiment;

FIG. 9a shows a schematic view of an arrangement of a monitoring apparatus according to one exemplary embodiment;

FIG. 9b shows an image of a monitoring apparatus;

FIG. 10 shows a view of a system according to one exemplary embodiment; and

FIG. 11 shows a schematic view of a mounting device for a charging cable plug.

### DETAILED DESCRIPTION

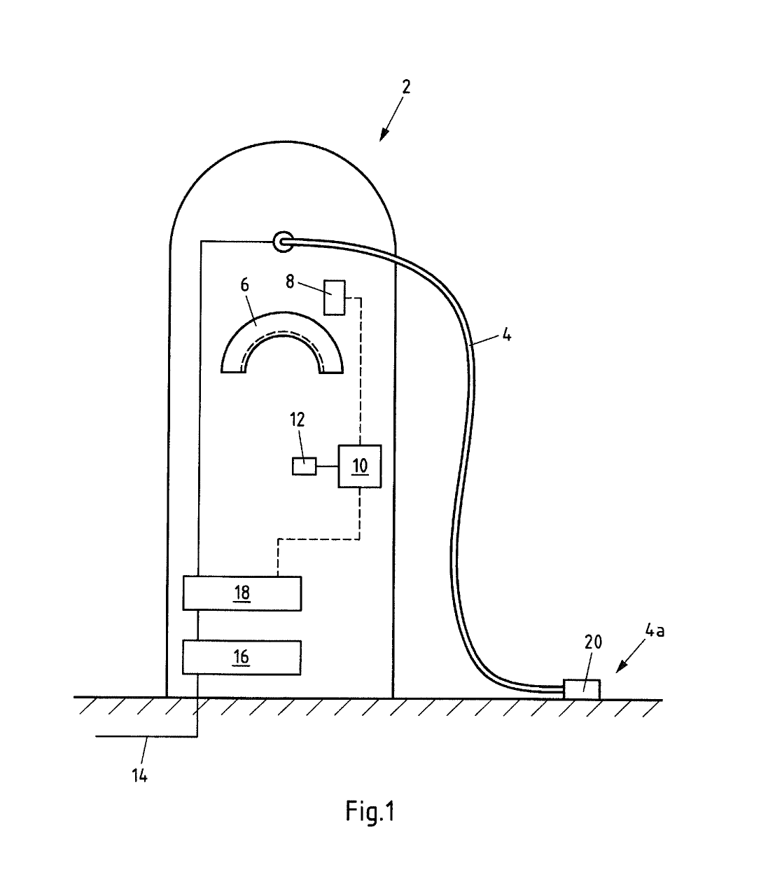

FIG. 1 shows a charging station 2 with a charging cable 4 and a charging cable holder 6. A monitoring apparatus 8 is arranged in the charging station 2. The monitoring apparatus 8 is in communication with a processor 10 which can load a program from a memory 12 in order to carry out the method described above and below. The memory 12 can further be designed to store measurement values and limit values, as described above and below.

The charging station 2 is connected to an electric distribution network 14 via a suitable connecting electrical system together with fuse and contactor. A charging electronics 18 manages the charging management, the measuring of related amounts of energy, communication with a server and everything else required for the charging operation. The charging electronics 18 monitors in particular the beginning and end of a charging operation and can notify the processor 10 of this.

FIG. 1 shows that the charging cable 4 is wound around the charging cable holder 6 not as intended, but rather lays with its free end 4a, in particular the charging plug 20 on the ground. This is not only unpleasant to look at, but can also lead to damage to the charging cable 4 or to accidents if a passer-by stumbles over the charging cable 4. It is therefore necessary to wind the charging cable 4 around the charging cable holder 6. In order to achieve this, the present arrangement, the present method and the present system are advantageous.

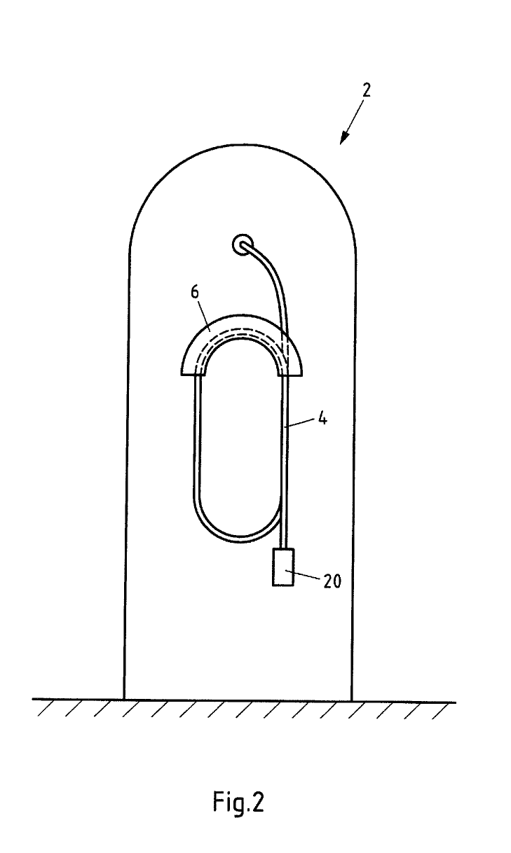

FIG. 2 shows a charging station 2 in which the charging cable 4 is wound correctly around the charging cable holder 6. It can be discerned that the charging cable 4 is wound around the charging cable holder 6 in one loop and the charging plug 20 hangs freely downwards at the charging cable holder 6.

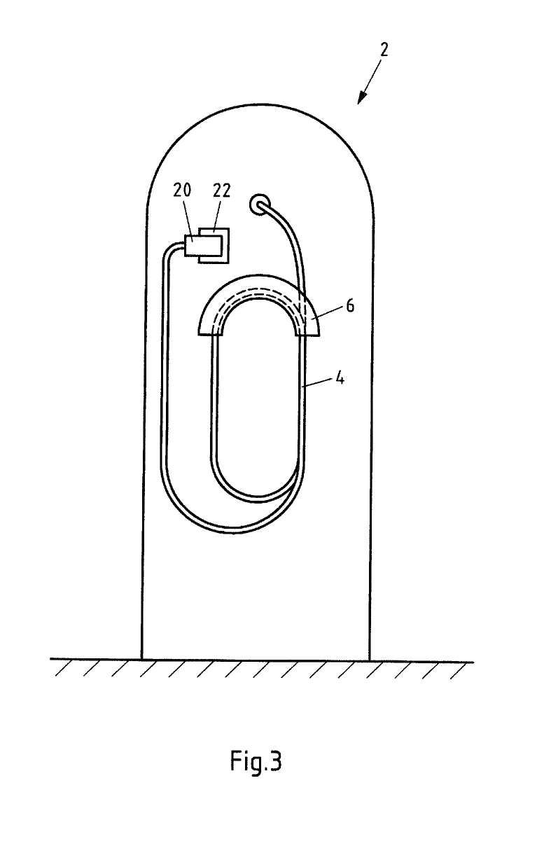

FIG. 3 shows a further example of a charging station 2 in which the charging cable 4 is wound around the charging cable holder 6. In this case, the charging cable plug 20 is still also arranged in a holder 22 for the charging cable plug 20 and fastened there.

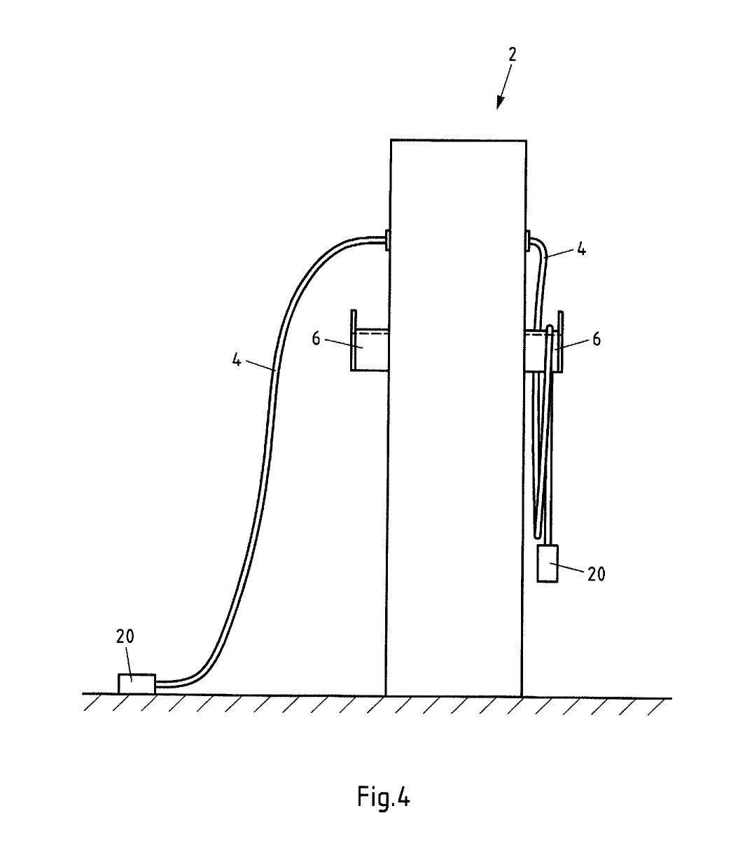

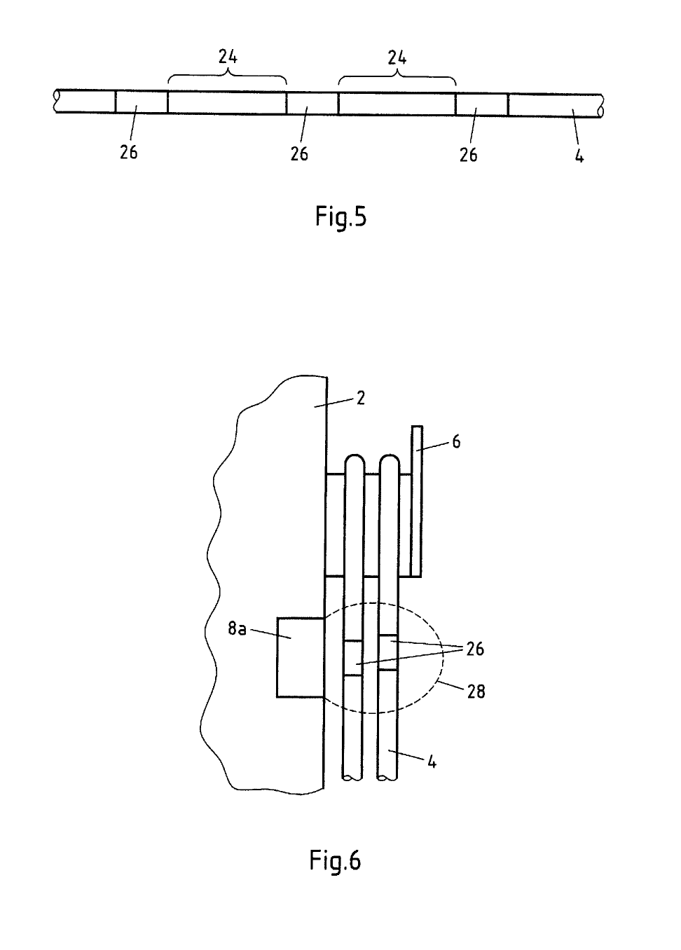

FIG. 4 shows a further charging station 2 in which two different charging cables 4 are arranged. The left charging cable 4 is not wound around the charging cable holder 6, whereas the right charging cable 4 is wound around the charging cable holder 6. In order to distinguish which of the two charging cables 4 is wound correctly around the charging cable holder 6, each individual charging cable 4 can be coded and thus be uniquely identifiable. To this end, at least one identification means can be provided on the charging cable 4, as is represented in FIG. 5.

FIG. 5 schematically shows a charging cable 4 in which identification means 26 are arranged at distances 24. The identification means 26 can for example be a colour coding on the charging cable 4. The identification means 26 can also for example be a barcode. Furthermore, it is possible for the identification means 26 to comprise at least one radio chip, in particular a near-field radio chip, for example an NFC or Bluetooth radio chip. It is advantageous when the identification means 26 are passive and are activated by an exciter field, in particular by a reading apparatus. This is in particular the case for NFC chips. In this case, both magnetic and electromagnetic fields can be used.

The distances 24 are selected such that respectively two identification means 26 are advantageously arranged in roughly the same region in the case of a complete winding of the charging cable 4 around the charging cable holder 6. This is for example shown in FIG. 6.

FIG. 6 shows a charging station 2 with a charging cable holder 6 and a charging cable 4 in a side view. A reading apparatus 8a is arranged in the charging station 2 as a monitoring apparatus 8. The reading apparatus 8a is in particular arranged in the region of the housing of the charging station and emits a query field 28. The query field 28 is in particular a high-frequency field, for example a magnetic or an electromagnetic field. The form of the query field 28 can be influenced by suitably arranging the transmission antenna inside the reading apparatus 8a such that the query field 28 can query identification means 26 only in a determined spatial region.

It can be seen in FIG. 6 that the charging cable 4 is wound around the charging cable holder 6 in two windings. It can also be discerned that the identification means 26 are roughly at the same height in the region of the reading apparatus 8. This is achieved by suitably selecting the distance 24 which preferably corresponds to the length of exactly one winding of the charging cable 4 around the charging cable holder 6.

The identification means 26 are read by the query field 28. In doing so, an identifier of the identification means 26 itself can be read and it can for example be detected by the reading apparatus 8a that exactly two identification means 26 are present. To this end, the identification means 26 should emit different identifiers from one another. In order to identify the charging cable 4, the identification means 26 can also bear an identifier of the charging cable 4. As a result, the reading apparatus 8a can also discern which charging cable 4 is wound around the charging cable holder 6. This is in particular appropriate in the case of an arrangement according to FIG. 4 in the case of which more than one charging cable 4 is arranged on the charging station 2. This prevents a charging cable 4 being wound up on an incorrect charging cable holder 6.

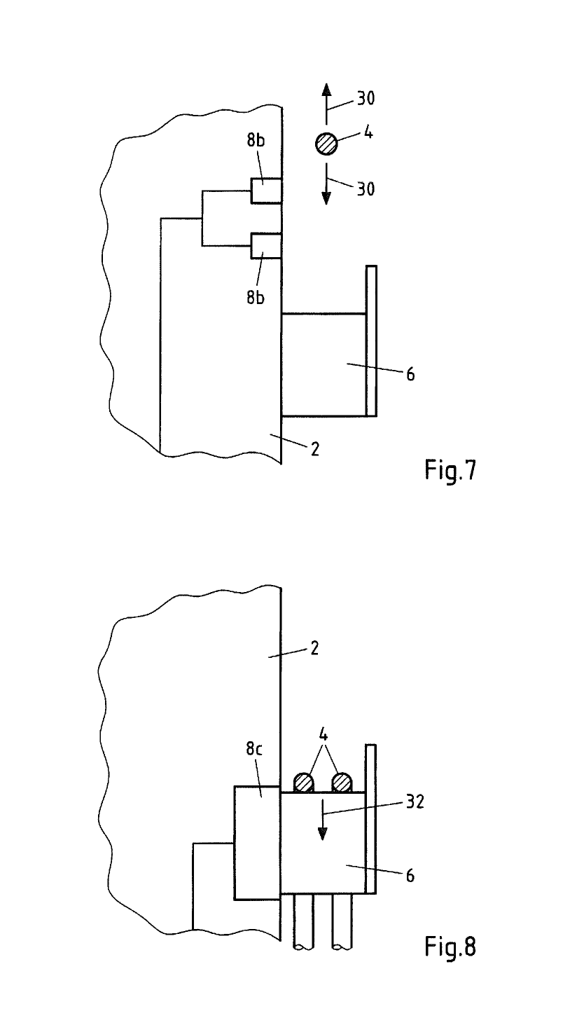

FIG. 7 shows a further example of a monitoring apparatus 8 which is formed by two adjacently arranged proximity sensors 8b inside the charging station 2. The proximity sensors 8b can discern when the charging cable 4 approaches them. A movement of the charging cable 4 in the direction 30 can be detected by the arrangement of the proximity sensors 8b next to one another. This allows it to be detected whether the charging cable 4 is placed on the charging cable holder 6 or is removed from the charging cable holder 6. If the charging cable 4 is moved downwards to the charging cable holder 6, the proximity sensors 8b detect this one after the other and it can be concluded that the charging cable 4 was placed in the charging cable holder 6.

If it is for example necessary for the charging cable 4 to be placed around the charging cable holder 6 in two loops, it is necessary for the proximity sensors 8b to detect precisely twice that a charging cable 4 was moved in the direction 30 downwards to the charging cable holder 6. Corresponding signalising takes place from the proximity sensors 8b to the processor 10.

FIG. 8 shows a further embodiment in the case of which the monitoring apparatus 8 comprises a weighing apparatus 8c. The weight force of the charging cable holder 6 together with the charging cable 4 placed thereon can be measured by means of the weighing apparatus 8c. The charging cable 4 exerts a force in the direction 32. If the charging cable 4 is wound fully around the charging cable holder 6 and is no longer on the ground, the entire weight force (minus the holding force at the contact point of the charging cable 4 at the charging station 2) of the charging cable 4 acts on the charging cable holder 6. This weight is greater than for example the weight if the charging cable holder 6 does not support any charging cable 4 or the charging cable 4 is partly on the ground. The weighing apparatus 8c can hereby detect by comparing the measured weight with a limit value whether the charging cable 4 was wound fully around the charging cable holder 6. Corresponding signalising also takes place here to the processor 10.

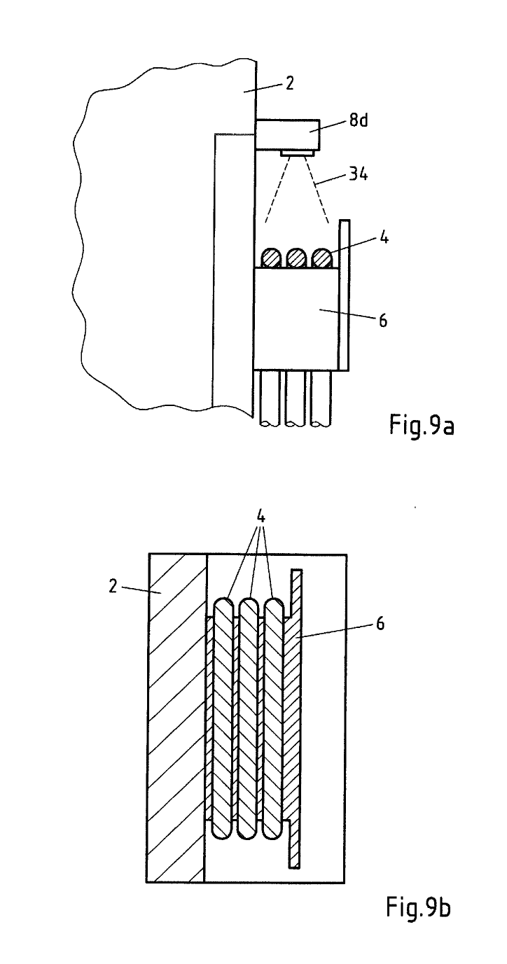

FIG. 9a shows a further embodiment in the case of which the monitoring apparatus comprises a camera 8d. The camera 8d can record an image in the viewing direction 34. This image comprises inter alia the charging cable holder 6 and possibly the charging cable 4 placed around the charging cable holder 6. A corresponding image is represented in FIG. 9b.

FIG. 9b shows an image of the camera 8d. The charging cable 4 can be discerned in the image which is wound around the charging cable holder 6 in three windings. The outer wall of the housing of the charging station 2 can also be discerned. The charging cable 4 can be detected by suitable pattern detection in the image according to FIG. 9b. It can also be detected how often the charging cable 4 was wound around the charging cable holder 6. This can be a measure for whether the charging cable 4 was wound correctly around the charging cable holder 6 and correspondingly the camera 8d can transmit a signal to the processor 10.

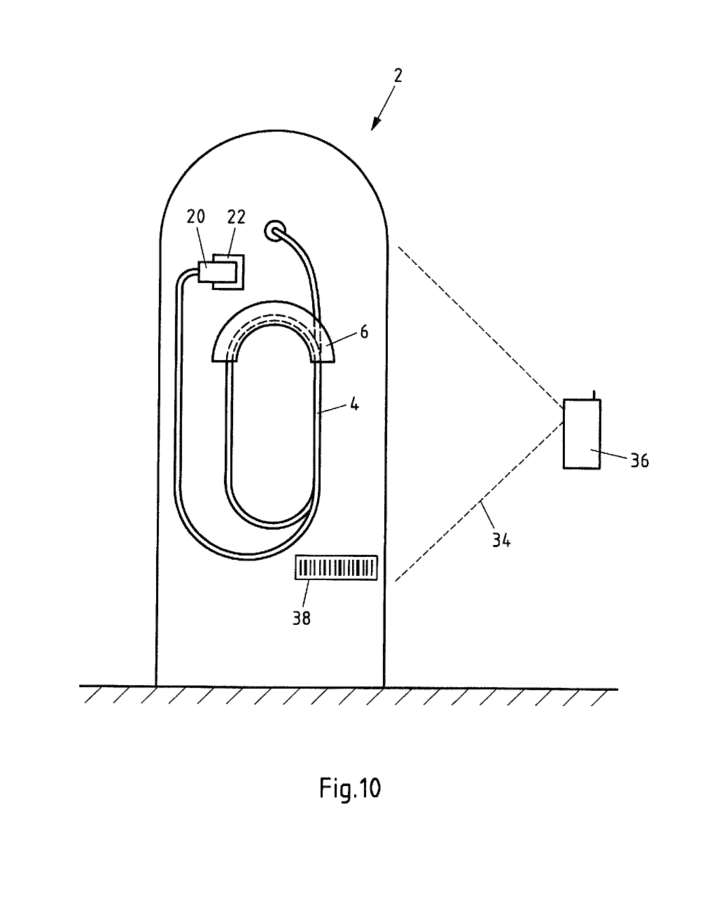

FIG. 10 shows a further embodiment in the case of which the charging station 2 is captured by an external mobile device 36. A camera is provided in the mobile device 36, for example a mobile radio device or another mobile communication device. An image of the charging station 2 can be recorded by means of the camera in the viewing direction 34. The housing of the charging station 2 and the charging cable 4 and the charging cable holder 6 can be detected in this image. It is also advantageous for an optical coding 38 for example in the form of a barcode, a colour coding, a QR code or the like to be detected in the image.

The image captured by the mobile device 36 can be transmitted via a long-distance connection for example a mobile connection and/or the internet to a server (not shown). The image can be captured by a mobile application in the mobile device 36. The mobile application can be programmed to perform at least parts of the previously-described method, in particular the detection of the charging station 2 or to support the charging cable 4 on the charging cable holder 6.

The image is assessed in the mobile device 36 or the server such that it is firstly detected where in the image the charging cable holder 6 is. It is then detected where the charging cable 4 is. This is in particular easy if the charging cable 4 stands out in contrast and/or colour from the charging cable holder 6 and the charging station 2. It is also possible for only the position of the charging cable 4 on the charging station 2 to be detected without detecting the charging cable holder 6. It can be detected by pattern detection that the charging cable 4 is fully wound up and it can in particular also be detected that the charging plug 20 is fastened in the holder 22.

Furthermore, the charging station 2 can be identified by the optical coding 38. By using the mobile application in the mobile device 36, the user can hereby prove to the service provider that they correctly wound up the charging cable 4 on the charging station 2 at a certain time. If this has been detected in the server, the user can be paid a bonus for this.

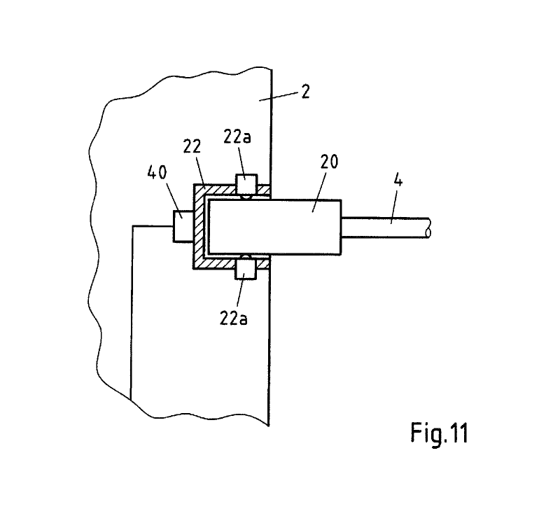

FIG. 11 shows an embodiment of a holder 22 for a charging cable plug 20. The charging cable 4 comprises the charging cable plug 20 at its end 4a. The charging cable plug can be plugged in a recess in the housing 2 which forms the holder 22. Retaining means 22a, for example spring force-driven retaining means, can securely lock the charging cable plug 20 in the holder 22. It is then necessary for the charging cable plug 20 to be removed from the holder 22 with a defined force. A testing apparatus 40 is also provided in the holder 22. It can be tested by means of the testing apparatus 40 whether the charging cable 4 or the charging cable plug 20 was plugged into the holder 22. Corresponding signalising can take place to the processor 10.

The charging station 2 is now operated as follows. A user begins a charging operation by plugging the charging plug 20 into the charging socket of their vehicle and enabling the charging operation. The charging operation is controlled between the charging electronics 18 and a charging regulator inside the vehicle. The end of the charging operation is detected by the charging electronics 18. The charging electronics 18 also detects that the charging plug 20 was removed from the electric vehicle. This point in time is relevant for the period within which the monitoring apparatus 8 has to monitor the placement of the charging cable 4 on the charging cable holder 6. It has been detected that the end of the charging operation no longer correlates with the point in time at which the charging cable 4 is placed back on the charging station 2. In fact, this is the point in time at which the charging cable 4 is removed from the corresponding socket of the vehicle. This point in time is communicated to the processor 10 by the charging electronics 18 and can also be understood as the end of the charging operation.

The processor 10 then activates the monitoring apparatus 8 for a defined period, for example five minutes. The monitoring apparatus 8 now activates the reading apparatus 8a, the proximity sensor 8b, the weighing apparatus 8c, the camera 8d and/or the like. They detect, as previously described, whether the charging cable 4 is placed correctly on the charging cable holder 6.

The processor 10 also initiates an electric verification of the charging cable 4 via the charging electronics 18. In doing so, the insulation resistance between the respective lines/leads can in particular be measured in the charging cable 4. The charging electronics 18 notifies the processor 10 that the insulation resistance is respectively within predefined limit values.

The monitoring apparatus 8 also notifies the processor 10 when the charging cable 4 has been placed correctly on the charging cable holder 6. The testing apparatus 40 can then also still inform the processor 10 whether the charging cable plug 20 has been locked correctly in the holder 22.

If all positive signals are present in the processor 10, the processor 10 can transmit a corresponding signal to a server such that a bonus system can be triggered.

It is also possible that the apparatuses 8a-d transmit their measurement values to the processor 10 and it compares the received measurement values with the measurement values stored in the memory 12. The comparison can be concluded in the processor 10 and therefore the processor 10 can determine based on the recorded measurement values whether the charging cable 4 has been placed correctly on the charging cable holder 6.

It is now possible by means of the present charging station 2 to ensure that a charging cable 4 has also been wound correctly on a charging cable holder 6 and therefore the risk of an accident due to the charging cable 4 remaining on the ground is reduced.

All references, including publications, patent applications, and patents cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) is to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A charging station, in particular a charging station for electric vehicles, comprising
a charging cable attached to the charging station in a fixed manner,
at least one charging cable holder arranged on the charging station and
at least one monitoring apparatus configured to monitor the position of the charging cable at the charging station, wherein the monitoring apparatus monitors whether the charging cable is placed around the charging cable holder in at least one loop,
wherein, after the charging cable has been installed, the monitoring apparatus is taught on the cable such that measurement values of the monitoring apparatus are recorded when the charging cable is placed around the charging cable holder in at least one loop and the recorded measurement values are stored as threshold values for the determination of whether the charging cable is placed around the charging cable holder in at least one loop.

2. The charging station according to claim 1,
wherein the monitoring apparatus comprises a weighing apparatus, wherein the weighing apparatus is configured to weigh the charging cable arranged on the charging cable holder in order to monitor whether the charging cable is wound around the charging cable holder in at least one loop, and/or
wherein the monitoring apparatus comprises an optical reading apparatus, wherein the optical reading apparatus is configured to optically detect the charging cable arranged on the charging cable holder in order to monitor whether the charging cable is wound around the charging cable holder in at least one loop.

3. The charging station according to claim 1, wherein at least two optical identification means, are arranged on the charging cable at distances to one another, wherein the identification means are identifiable by means of the monitoring apparatus, in particular in that the monitoring apparatus is configured to detect the identification means in a spatially-limited region.

4. The charging station according to claim 3, wherein the monitoring apparatus stores a number and/or identifiers of identification means which are representative of the winding of the charging cable around the charging cable holder.

5. The charging station according to claim 1, wherein a charging electronics is arranged in the charging station, wherein the charging electronics is configured to detect an end of a charging operation and wherein the charging electronics activates the monitoring apparatus in particular for at least one defined period when an end of a charging operation is detected.

6. The charging station according to claim 5,
wherein the monitoring apparatus, after being activated by the charging electronics, monitors for a defined period whether the charging cable is wound around the charging cable holder in at least one loop, and
wherein the monitoring apparatus emits a confirmation signal when, within the defined period, it was detected that the charging cable is wound around the charging cable holder state, and
wherein the monitoring apparatus emits an error signal at the end of the defined period without it being detected that the charging cable was wound around the charging cable holder.

7. The charging station according to claim 5,
wherein the monitoring apparatus, after being activated by the charging electronics, monitors the electrical state of the charging cable, in particular measures an insulation resistance between at least respectively two conductors of the charging cable and compares it with a threshold value and
wherein the monitoring apparatus emits a confirmation signal when, within the defined period, it was detected that the electrical state of the charging cable was positively monitored, and
wherein the monitoring apparatus emits an error signal at the end of the defined period without it being detected that the electrical state of the charging cable was negatively monitored.

8. The charging station according to claim 1, wherein a mounting socket is provided for a charging cable plug of the charging cable, wherein a testing apparatus is arranged in the mounting socket configured to test the presence of the charging cable plug in the mounting socket, in particular in that the testing apparatus comprises a limit switch, a Hall sensor and/or a microswitch.

9. The charging station according to claim 1, wherein a processor in the charging station monitors a confirmation signal from the monitoring apparatus and when the confirmation signal is received within a time frame emits a release signal.

10. A method for monitoring a charging cable at a charging station, wherein the charging cable is attached to the charging station in a fixed manner, the method comprising the steps of:
monitoring, by means of a monitoring apparatus, whether the charging cable is placed around the charging cable holder in at least one loop, and
teaching the monitoring apparatus when the charging cable is installed on the charging cable holder such that measurement values of the monitoring apparatus are recorded when the charging cable is placed around the charging cable holder in at least one loop, and
storing the recorded measurement values as threshold values for the determination of whether the charging cable is placed around the charging cable holder in at least one loop.

11. The method according to claim 10, further comprising the step of comparing measurement values of the monitoring apparatus with previously determined threshold values in order to detect whether the charging cable is placed around the charging cable holder in at least one loop.

12. The method according to claim 10, wherein, in order to detect whether the charging cable is placed around the charging cable holder in at least one loop, the method further comprises the steps of:
capturing an image of the charging station,
carrying out a pattern detection in the captured image such that the charging cable holder and the charging cable are detected, and
determining the position of the charging cable in relation to the charging cable holder in the image.

13. The method according to claim 12, further comprising the steps of:
capturing an optical identification means of the charging station, in particular a QR code, in the image of the charging station, and
detecting, by means of the optical identification means, which charging station is captured in the image.

14. A system with a charging station according to claim 1, wherein the monitoring apparatus is formed by a mobile communication device differentiated from the charging station and wherein the mobile communication device forms the optical reading apparatus.
